(19) United States
(12) Patent Application Publication
(10) Pub. No.: US 2009/0325384 A1
(43) Pub. Date: Dec. 31, 2009

(54) METHOD OF MANUFACTURING SEMICONDUCTOR DEVICE

(76) Inventor: Noriteru Yamada, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/404,706

(22) Filed: Mar. 16, 2009

(30) Foreign Application Priority Data
Jun. 27, 2008 (JP) 2008-168714

(51) Int. Cl. H01L 21/302; H01L 21/306; H01L 21/314

(52) U.S. Cl. 438/692; 438/700; 438/778; 257/E21.23; 257/E21.214; 257/E21.266

(57) ABSTRACT

A method of manufacturing a semiconductor device has forming a first insulating film on a low dielectric constant film; etching the first insulating film and the low dielectric constant film to form a trench in a region in which the wiring layer is to be formed; forming a first barrier metal film in the trench and on the first insulating film; forming a film of a conductive material on the first barrier metal film, thereby burying the conductive material in the trench to form a conductor layer; polishing and planarizing the conductor layer, the first barrier metal film and the first insulating film by CMP using a slurry, wherein the first insulating film is not completely removed; and etching the remained first insulating film after the planarization by the CMP manner.

### CROSS-REFERENCE TO RELATED APPLICATION

This application is based upon and claims the benefit of priority from the prior Japanese Patent Application No. 2008-168714, filed on Jun. 27, 2008, the entire contents of which are incorporated herein by reference.

### BACKGROUND OF THE INVENTION

1. Field of the Invention

The present invention relates to a method of manufacturing a semiconductor device that has a damascene wiring structure using a low dielectric constant film (low-k film).

2. Background Art

As miniaturization of semiconductor devices advances, a resistance-capacitance (RC) delay is emerging as a problem.

A solution to this problem that is being investigated is to reduce the RC delay by reducing the interline capacitance and the interlayer capacitance by using a low dielectric constant film (low-k film) in an interlayer insulating film (see Japanese Patent Laid-Open No. 2007-220934, for example).

### SUMMARY OF THE INVENTION

According to one aspect of the present invention, there is provided: a method of manufacturing a semiconductor device having a wiring layer in a low dielectric constant film, comprising:

forming a first insulating film on the low dielectric constant film;

etching the first insulating film and the low dielectric constant film to form a trench in a region in which the wiring layer is to be formed;

forming a first barrier metal film in the trench and on the first insulating film;

forming a film of a conductive material on the first barrier metal film, thereby burying the conductive material in the trench to form a conductor layer;

polishing and planarizing the conductor layer, the first barrier metal film and the first insulating film by CMP using a slurry, wherein the first insulating film is not completely removed; and

etching the remained first insulating film after the planarization by the CMP manner.

### BRIEF DESCRIPTION OF THE DRAWINGS

FIG. 1A is a cross-sectional view showing a step of a comparison example of a method of manufacturing a semiconductor device;

FIG. 1B is a cross-sectional view showing a step of a comparison example of the method of manufacturing a semiconductor device, is continuous from FIG. 1A;

FIG. 1C is a cross-sectional view showing a step of a comparison example of the method of manufacturing a semiconductor device, is continuous from FIG. 1B;

FIG. 1D is a cross-sectional view showing a step of a comparison example of the method of manufacturing a semiconductor device, is continuous from FIG. 1C;

FIG. 1E is a cross-sectional view showing a step of a comparison example of the method of manufacturing a semiconductor device, is continuous from FIG. 1D;

FIG. 1F is a cross-sectional view showing a step of a comparison example of the method of manufacturing a semiconductor device, is continuous from FIG. 1E;

FIG. 1G is a cross-sectional view showing a step of a comparison example of the method of manufacturing a semiconductor device, is continuous from FIG. 1F;

FIG. 1H is a cross-sectional view showing a step of a comparison example of the method of manufacturing a semiconductor device, is continuous from FIG. 1G;

FIG. 2 is a cross-sectional view for illustrating the dependency of the amount of CMP shavings on the wiring density in a region in which a sparse wiring pattern is formed in the comparison example;

FIG. 3A is a cross-sectional view showing a step of a method of manufacturing a semiconductor device according to an embodiment 1;

FIG. 3B is a cross-sectional view showing a step of a method of manufacturing a semiconductor device according to an embodiment 1, is continuous from FIG. 3A;

FIG. 3C is a cross-sectional view showing a step of a method of manufacturing a semiconductor device according to an embodiment 1, is continuous from FIG. 3B;

FIG. 3D is a cross-sectional view showing a step of a method of manufacturing a semiconductor device according to an embodiment 1, is continuous from FIG. 3C;

FIG. 3E is a cross-sectional view showing a step of a method of manufacturing a semiconductor device according to an embodiment 1, is continuous from FIG. 3D;

FIG. 3F is a cross-sectional view showing a step of a method of manufacturing a semiconductor device according to an embodiment 1, is continuous from FIG. 3E;

FIG. 3G is a cross-sectional view showing a step of a method of manufacturing a semiconductor device according to an embodiment 1, is continuous from FIG. 3F;

FIG. 3H is a cross-sectional view showing a step of a method of manufacturing a semiconductor device according to an embodiment 1, is continuous from FIG. 3G; and

FIG. 3I is a cross-sectional view showing a step of a method of manufacturing a semiconductor device according to an embodiment 1, is continuous from FIG. 3H.

### DETAILED DESCRIPTION

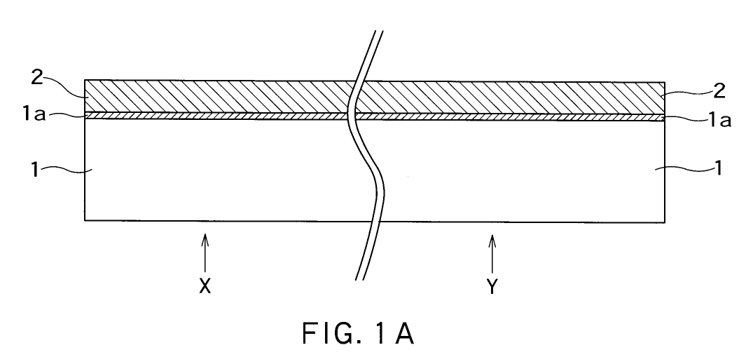

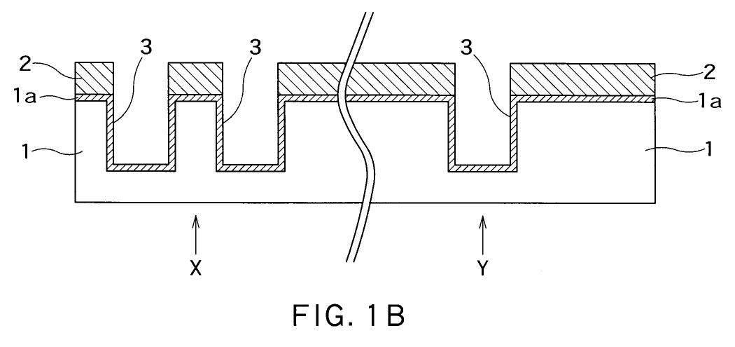

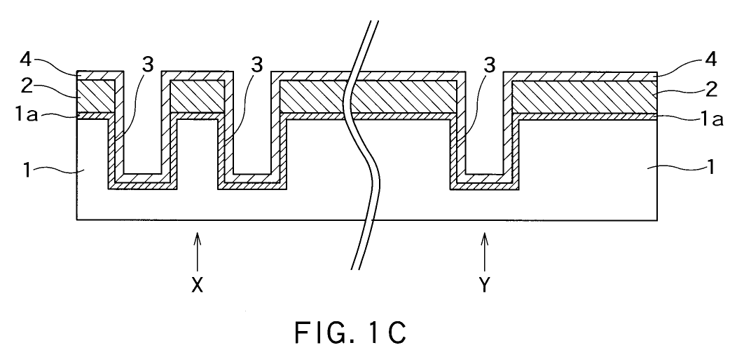

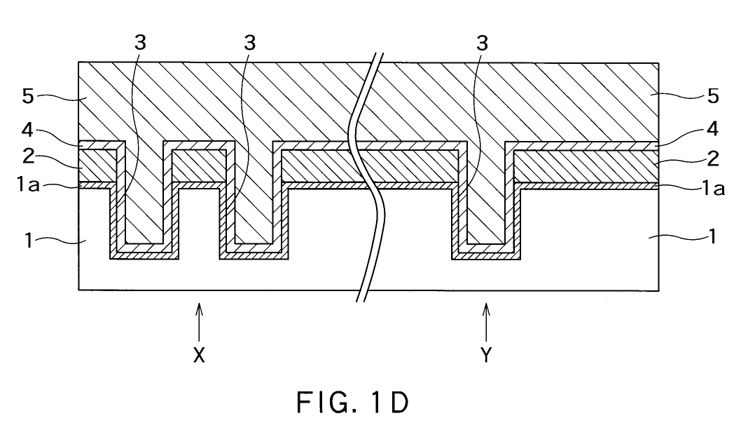

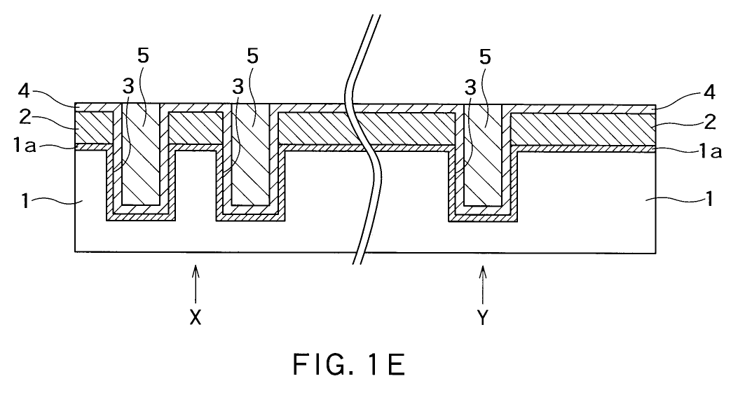

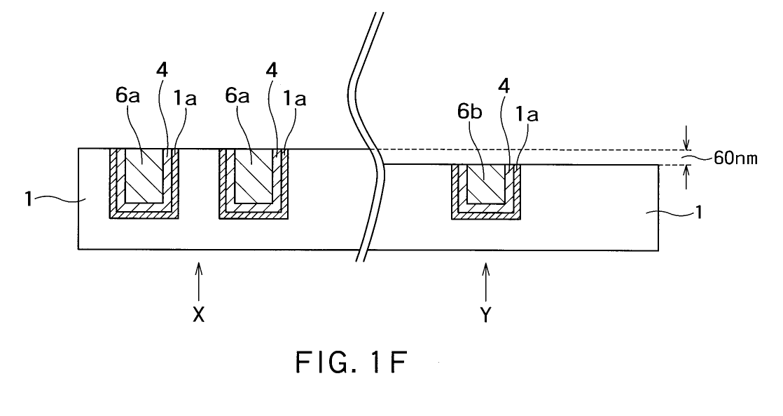

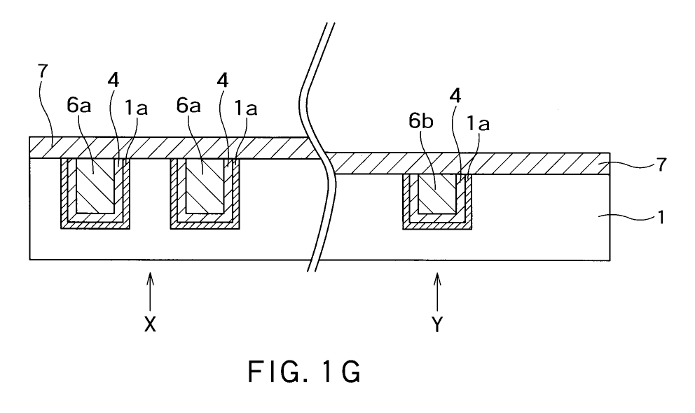

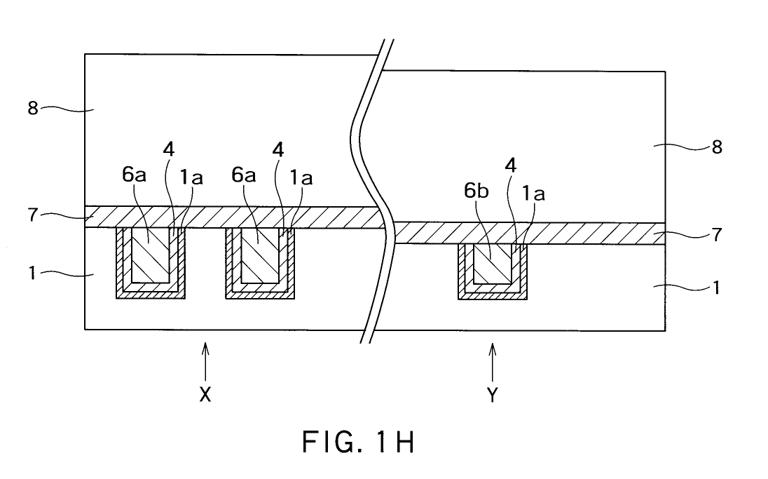

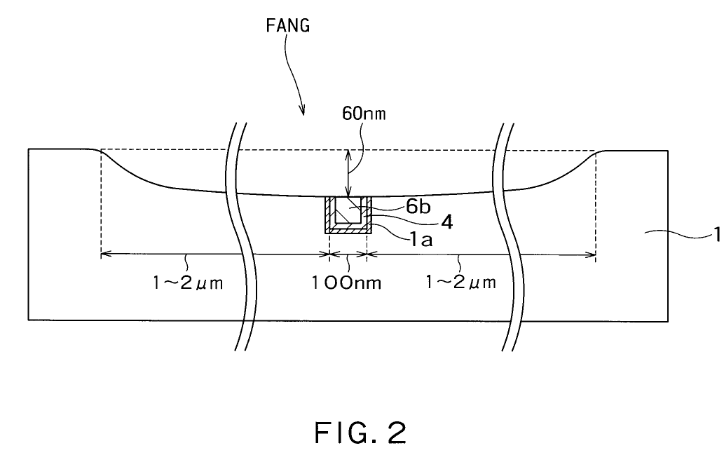

FIGS. 1A to 1H are cross-sectional views showing different steps of a comparison example of a method of manufacturing a semiconductor device. FIG. 2 is a cross-sectional view for illustrating the dependency of the amount of CMP shavings on the wiring density in a region in which a sparse wiring pattern is formed in the comparison example.

A dense wiring pattern forming region “X” in FIGS. 1A to 1H is a region in which the surface density of the wiring pattern on the wafer surface is high. On the other hand, a sparse wiring pattern forming region “Y” is a region in which the surface density of the wiring pattern on the wafer surface is low.

First, on a low dielectric constant film 1 formed on a semiconductor substrate (not shown), a cap film 2 is formed by plasma chemical vapor deposition (PCVD) (FIG. 1A). The upper surface of the low dielectric constant film 1 is damaged by the plasma during the PCVD, and a damaged layer la is formed. The cap film 2 is intended for the later rework of lithography to form a trench in the case where damascene wiring is formed in the low dielectric constant film 1. That is, when the resist film is removed by an ashing apparatus in the rework, the cap film 2 prevents damage to the low-k film by the ashing apparatus.

Then, the cap film 2 and an upper part of the low dielectric constant film 1 are etched by reactive ion etching (RIE) to form a trench 3 in a region in which a wiring layer is to be formed later (FIG. 1B). The inner surface of the trench 3 in the low dielectric constant film 1 is damaged by the plasma during the RIE, and a damaged layer 1a is also formed on the inner surface of the trench 3.

Then, a barrier metal film 4 is formed in the trench 3 and on the cap film 2 by plasma enhanced chemical vapor deposition (PECVD), for example (FIG. 1C). The barrier metal film 4 prevents a conductive material to be used later from diffusing into the low dielectric constant film 1.

Then, a seed layer is formed on the surface of the barrier metal film 4, and then, a Cu film is formed on the surface of the seed layer by electroplating, for example. Thus, a conductor layer 5 made of Cu is formed in the trench 3 having the barrier metal film 4 formed therein (FIG. 1D).

Then, using the barrier metal film 4 as a stopper, the conductor layer 5 is polished and planarized by chemical mechanical polishing (CMP) (FIG. 1E).

Then, the barrier metal film 4, the cap film 2 and the damaged layer 1a are polished and planarized by touch up CMP (FIG. 1F). In this way, wiring layers 6a, 6b are formed.

Note that the touch up CMP involves removing the barrier metal film 4 on the field to insulate the wiring layers 6a and 6b from each other and removing the cap film 2, the damaged layer 1a and a part of the low dielectric constant film 1 to complete the wiring layers in the low dielectric constant film 1 while planarizing the polished surface.

In the sparse wiring pattern forming region “Y”, the low dielectric constant film 1 is excessively shaved (by about 60 nm) because of the dependency of the amount of shaving of the low-k film on the density of the wiring pattern described later. More specifically, the thickness of the wiring layer 6b in the sparse wiring pattern forming region “Y” is smaller than the thickness of the wiring layer 6a in the dense wiring pattern forming region “X”.

Then, a barrier metal film 7 is formed on the upper surface of the wiring layers 6a, 6b (FIG. 1G).

Then, an interlayer dielectric (ILD) film 8, which is an insulating film, is formed (FIG. 1H). The ILD film 8 has a stepped upper surface that conforms to the stepped upper surface of the low dielectric constant film 1 that varies in height between the dense wiring pattern forming region “X” and the sparse wiring pattern forming region “Y”.

It can be considered that the dependency of the amount of shaving of the low-k film on the density of the wiring pattern is due to two factors.

One of the factors is that a slurry having a low wettability with the low-k film and a high wettability with Cu is used in the touch up CMP, so that abrasive grains in the slurry are collected on the Cu wiring pattern sparsely arranged. The other factor is that the CMP rate for the part of the low-k film that is damaged by the plasma during the RIE and PECVD is higher than the rate for the part that is not damaged.

The two factors cooperate to locally increase the CMP rate in the region in which the sparse wiring pattern is formed. That is, as the wiring pattern becomes sparser, the amount of shaving increases. As a result, the region in which the sparse wiring pattern is formed has a cross section in which the amount of CMP shaving depends on the wiring density as shown in FIG. 2.

Therefore, the thickness of the wiring layer in the region in which the sparse wiring pattern is formed tends to be smaller. In particular, for the low-k film, the tendency becomes more significant as the dielectric constant decreases (when the k value is equal to or lower than 3).

For example, supposing that the dense wiring pattern forming region “X” is a region in which the local proportion of wiring patterns of sizes of about 10-um square is close to 50%, the tendency hardly appears in the dense wiring pattern forming region “X”. On the other hand, supposing that the sparse wiring pattern forming region “Y” is a region in which the local proportion of wiring patterns of sizes of about 10-um square is equal to or lower than 10%, the tendency is remarkable in the sparse wiring pattern forming region “Y”.

As described above, because of the dependency of the amount of shaving of the low-k film on the density of the wiring pattern, the height of the wiring layer varies. This, in turn, can pose a problem that the variation in resistance of the metal wiring (Cu) increases.

In addition, there is a future possibility that the k value of the low-k film is further reduced, and CMP of the low-k film itself can hardly be accomplished.

Thus, according to an embodiment of the present invention, there is provided a method of manufacturing a semiconductor device in which the in-plane variation of the wiring resistance is reduced.

In the following, an embodiment of the present invention will be described with reference to the drawings.

### Embodiment 1

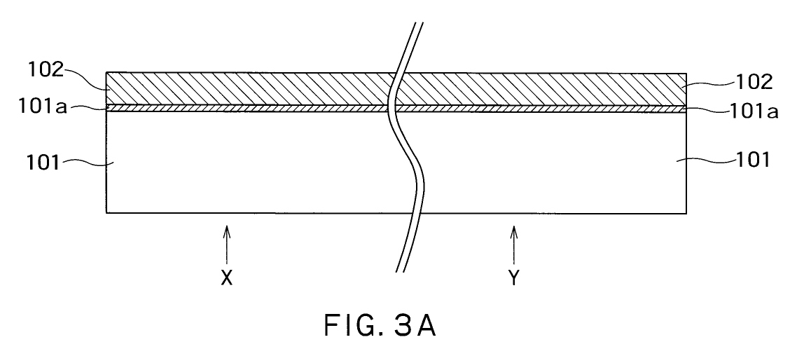

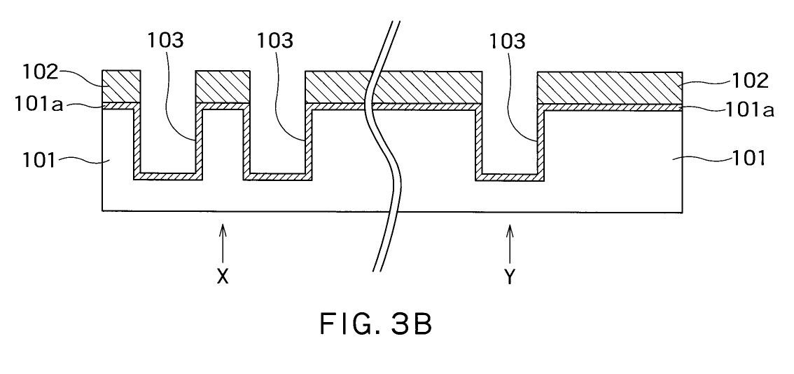

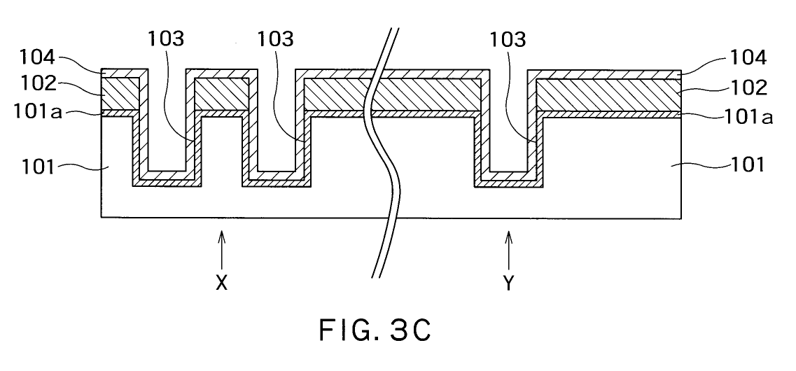

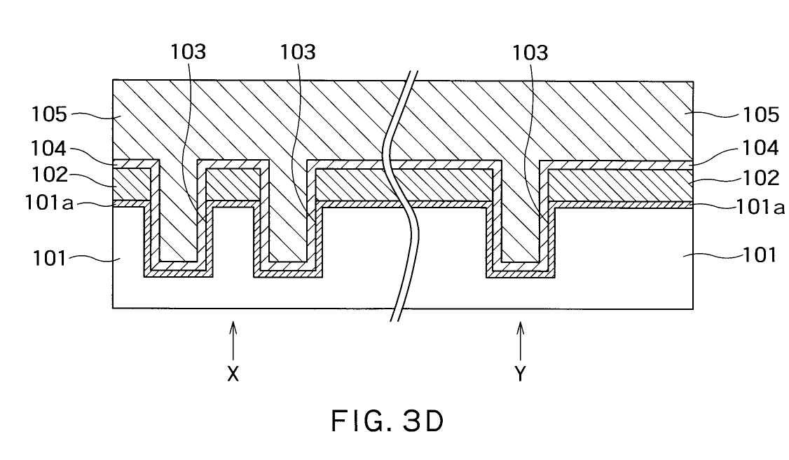

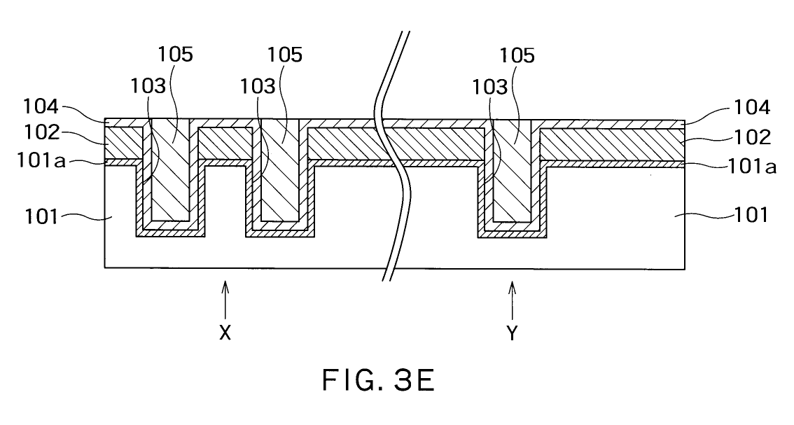

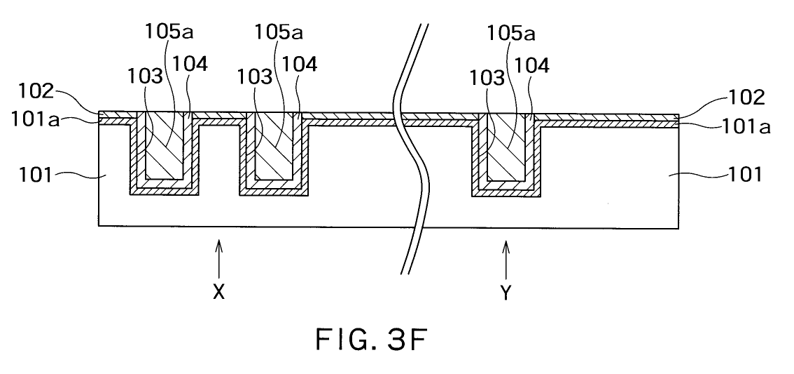

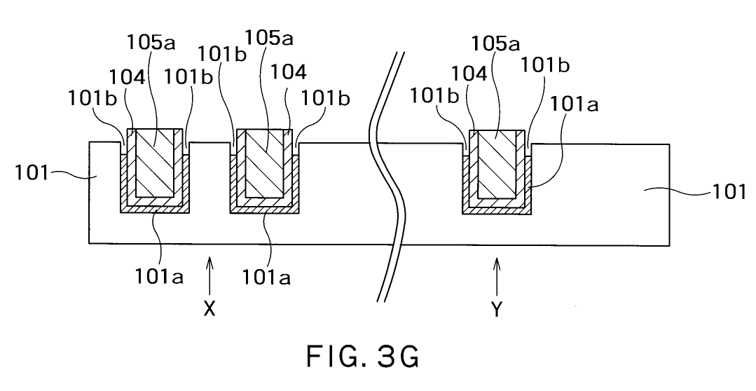

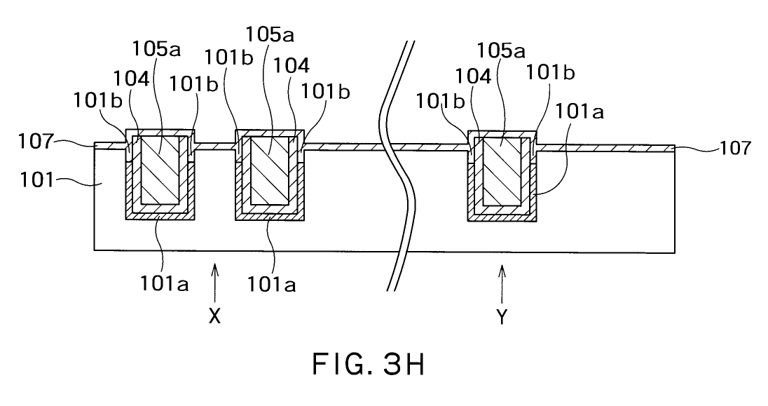

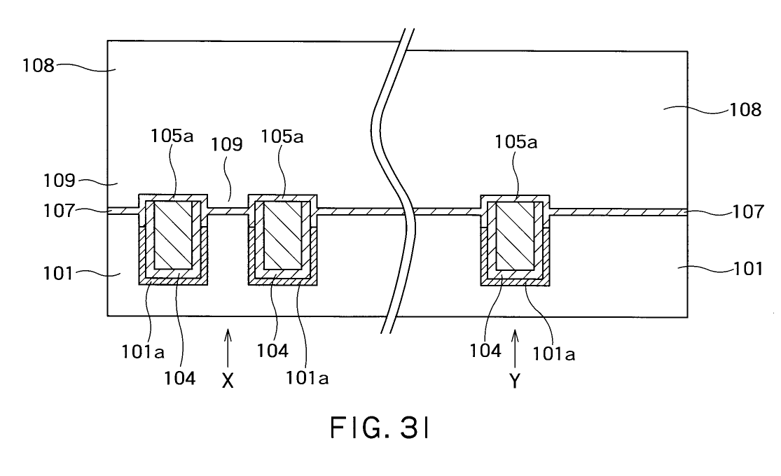

FIGS. 3A to 3I are cross-sectional views showing different steps of a method of manufacturing a semiconductor device according to an embodiment 1.

As in the comparison example, in FIGS. 3A to 3I, a dense wiring pattern forming region “X” is a region in which the surface density of the wiring pattern on the wafer surface is high. On the other hand, a sparse wiring pattern forming region “Y” is a region in which the surface density of the wiring pattern on the wafer surface is low. For example, it is supposed that the dense wiring pattern forming region “X” is a region in which the local proportion of wiring patterns of sizes of about 10-um square is close to 50%, and the sparse wiring pattern forming region “Y” is a region in which the local proportion of wiring patterns of sizes of about 10-um square is equal to or lower than 10%. In this way, it is supposed that the wafer surface includes regions that differ in surface density of the wiring layer.

First, on a low dielectric constant film 101 formed on a semiconductor substrate (not shown), a cap film (insulating film) 102 is formed by PCVD (FIG. 3A).

As the low dielectric constant film 101, a film having a k value lower than 3, such as of SiCo and SiCoH, is used. The upper surface of the low dielectric constant film 101 is damaged by the plasma during the PCVD, and a damaged layer 101a is formed. As the cap film 2, a TEOS film (SiO₂ film) is used, for example.

Then, the cap film 102 and an upper part of the low dielectric constant film 101 are etched by RIE to form a trench 103 that penetrates through the cap film 102 into the low dielectric constant film 101 in a region in which a wiring layer 105a is to be formed later (FIG. 3B). At least the inner surface of the trench 103 in the low dielectric constant film 101 is damaged by the plasma during the RIE, and a damaged layer 101a is also formed on the inner surface of the trench 103.

Then, a barrier metal film 104 is formed in the trench 103 and on the cap film 102 by PECVD, for example (FIG. 3C). The barrier metal film 104 prevents a conductive material to be used later from diffusing into the low dielectric constant film 101.

As the barrier metal film 104, a Ta film or a TaN/Ta multilayer film is used, for example.

Then, a seed layer is formed on the surface of the barrier metal film 104, and then, a film of a conductive material (Cu in this embodiment) is formed on the upper surface of the seed layer by electroplating, for example. Thus, the conductive material is buried in the trench 103 having the barrier metal film 104 formed therein to form a conductor layer 105 (FIG. 3D).

Then, using the barrier metal film 104 as a stopper, the conductor layer 105 is planarized by (first) CMP (FIG. 3E).

The first CMP is performed using CMS7501/7552 (manufactured by JSR Corporation) and ammonium persulfate as a slurry under conditions that the flow rate is 300 cc/min, IS1000 (manufactured by Nitta Haas Incorporated) is used as the polishing pad, the load is 300 gf/cm², the number of revolutions of the carrier/table is 100 rpm, and the polishing duration is 120 sec, for example.

Then, the conductor layer 105, the barrier metal film 104 and the cap film 102 are polished and planarized by (second) CMP in such a manner that the cap film 102 is not completely removed. In this way, a wiring layer 105a is formed in the trench 103 (FIG. 3F). The thickness of the planarized cap film 102 is about 40 nm, for example.

Since the polishing of the cap film 102 in the second CMP is stopped part way, the low dielectric constant film 101 is not exposed. Therefore, occurrence of the dependency of the amount of CMP shaving on the density of the wiring described above is prevented. That is, at this point in time, the thickness of the wiring layer 105a in the dense wiring pattern forming region “X” is equal to the thickness of the wiring layer 105a in the sparse wiring pattern forming region “Y”.

In the second CMP, a slurry having a higher wettability with the conductive material (Cu in this embodiment) than with the low dielectric constant film is used. The second CMP is performed using CMS8401/8452 (manufactured by SR Corporation) and hydrogen peroxide as a slurry under conditions that the flow rate is 300 cc/min, IS1000 (manufactured by Nitta Haas Incorporated) is used as the polishing pad, the load is 300 gf/cm², the number of revolutions of the carrier/table is 100 rpm, and the polishing duration is 60 sec, for example.

Then, the cap film 102 remaining after the planarization by the second CMP is selectively removed by wet etching using dilute hydrofluoric acid (DHF), for example (FIG. 3G).

The wiring layer 105a is not etched in this step. That is, excessive polishing of the wiring layer 105a in the region in which the sparse wiring pattern is formed is prevented, and thus, further reduction of the thickness of the wiring layer 105a is prevented. That is, the in-plane variation of the wiring resistance is reduced.

In this embodiment, the damaged layer 101a formed on the upper surface of the low dielectric constant film 101 by the PCVD is also etched along with the cap film 102. As a result, a recess 101b is formed in the vicinity of the top part of the barrier metal film 104 (the region in which the damaged layer 101a has existed).

The etch back process for selectively etching the remaining cap film 102 may be RIE instead of wet etching, although the damage to the low dielectric constant film 101 has to be considered.

Then, after the cap film 102 is selectively etched, a barrier metal film 107 that prevents diffusion of a conductive material (Cu in this embodiment) from wiring layers 6a, 6b to be formed later is formed at least on the upper surface of the wiring layer 105a by PECVD (FIG. 3H). As the barrier metal film 107, a SiCN film is used, for example.

Then, an interlayer dielectric (ILD) film 108, which is an insulating film, is formed (FIG. 3I). As the ILD film 108, the same film as the low dielectric constant film 101 is used, for example. Since there is no dependency of the amount of CMP shaving on the density of the wiring, the height difference of the upper surface of the ILD film 8 between the dense wiring pattern forming region “X” and the sparse wiring pattern forming region “Y” is smaller than the height difference in the comparison example described earlier.

The barrier metal film (stopper film) 107 having a high k value exists on an upper part of the side wall of the wiring layer 105a. In particular, in the dense wiring pattern forming region “X”, the k value is expected to increase slightly. However, when the ILD film 108 is formed, an air gap can be formed because of the stepped configuration of the barrier metal film 107. In such a case, the wiring capacitance in the dense wiring pattern forming region “X” can be effectively reduced.

Instead of the barrier metal film 107 described above, a barrier metal film may be formed on top of the wiring layer (Cu) by applying a step of selectively forming a barrier metal film on top of the Cu wiring by a post-processing after CMP, and the ILD film (low-k film) 108 may be formed thereon. That is, the present invention is not limited to the presence or absence of use of the stopper film. In principle, the present invention is applied based on a concept that the low dielectric constant film 101 is not polished by CMP.

As described above with reference to FIG. 3F, polishing by CMP is stopped before the cap film 102 is completely removed. Thus, for example, the cap film 102 may have a multilayer structure including an upper film that is disposed at an upper position and has a higher CMP polishing rate and a lower film that is disposed at a lower position and has a lower CMP polishing rate. In that case, the controllability of the amount of the cap film 102 polished by CMP is improved.

Furthermore, the lower film of the cap film 102 may be characterized by a high removability by wet etching. In that case, the removability of the cap film 102 by the later wet etching is improved.

As described above, according to the method of manufacturing a semiconductor device according to this embodiment, the in-plane variation of the wiring resistance can be reduced.

What is claimed is:

1. A method of manufacturing a semiconductor device having a wiring layer in a low dielectric constant film, comprising:
forming a first insulating film on the low dielectric constant film;
etching the first insulating film and the low dielectric constant film to form a trench in a region in which the wiring layer is to be formed;
forming a first barrier metal film in the trench and on the first insulating film;
forming a film of a conductive material on the first barrier metal film, thereby burying the conductive material in the trench to form a conductor layer;
polishing and planarizing the conductor layer, the first barrier metal film and the first insulating film by CMP using a slurry, wherein the first insulating film is not completely removed; and
etching the remained first insulating film after the planarization by the CMP manner.

2. The method of claim 1, wherein the conductive material is Cu.

3. The method of claim 1, wherein the slurry used in the CMP for planarization performed in such a manner that the first insulating film is not completely removed has a higher wettability with the conductive material than with the low dielectric constant film.

4. The method of claim 1, wherein the remained first insulating film is etched by wet etching manner.

5. The method of claim 4, wherein a damaged layer formed on the upper surface of the low dielectric constant film is etched by the wet etching manner.

6. The method of claim 4, wherein, after the remained first insulating film is etched by the wet etching manner, a second barrier metal film is formed at least on the upper surface of the wiring layer, and then, a second insulating film is formed.

7. The method of claim 1, wherein a wafer surface includes regions that differ in surface density of the wiring layer.

8. The method of claim 1, wherein the first barrier metal film is a Ta film or a TaN/Ta multilayer film.

9. The method of claim 2, wherein the first barrier metal film is a Ta film or a TaN/Ta multilayer film.

10. The method of claim 1, wherein the low dielectric constant film is a film of SiCo or SiCoH.

11. The method of claim 2, wherein the low dielectric constant film is a film of SiCo or SiCoH.

12. The method of claim 3, wherein the low dielectric constant film is a film of SiCo or SiCoH.

13. The method of claim 1, wherein, after the conductor layer is formed, the conductor layer is planarized by CMP using the first barrier metal film on the first insulating film as a stopper.

14. The method of claim 1, wherein the first insulating film includes an upper film that is disposed at an upper position and has a higher CMP polishing rate and a lower film that is disposed at a lower position and has a lower CMP polishing rate.
